(19) United States
(12) Patent Application Publication
(10) Pub. No.: US 2025/0224366 A1
(43) Pub. Date: Jul. 10, 2025

(54) Dual-gate organic electrochemical transistors

(71) Applicant: THE HONG KONG POLYTECHNIC UNIVERSITY, Hong Kong (CN)

(72) Inventors: Feng YAN, Hong Kong (CN); Anneng YANG, Hong Kong (CN)

(21) Appl. No.: 19/090,487

(22) Filed: Mar. 26, 2025

Related U.S. Application Data
(62) Division of application No. 15/929,455, filed on May 4, 2020.

(51) Int. Cl. G01N 27/414

(52) U.S. Cl. CPC G01N 27/4145

(57) ABSTRACT

A transistor comprising: a source electrode; a drain electrode; a channel comprising an organic semiconductor between the source electrode and the drain electrode; a plurality of gate electrodes; and an electrolyte, wherein the electrolyte contacts the gate electrodes and the channel, and wherein at least one gate electrode comprises an oxidoreductase and at least one gate electrode does not comprise an oxidoreductase, and methods for detecting and/or determining the concentration of an analyte in a sample using the transistor comprising: (i) applying a voltage to the at least one gate electrode which does not comprise an oxidoreductase; (ii) contacting the test sample in the transistor; (iii) applying the voltage used in (i) to the at least one gate electrode which comprises an oxidoreductase, (iv) removing the voltage from the at least one gate electrode which does not comprise an oxidoreductase; wherein (iii) and (iv) occur simultaneously.

### CROSS-REFERENCE TO RELATED APPLICATIONS

This application is a divisional application of U.S. Non-Provisional patent application Ser. No. 15/929,455, filed on May 4, 2020, the contents of which being hereby incorporated by reference in their entirety for all purposes.

### TECHNICAL FIELD

The present invention relates generally the field of biosensors. More specifically, the present invention relates to biosensors based on organic electrochemical transistors (OECTs), and methods for the use thereof.

### BACKGROUND

The following discussion of the background of the invention is merely provided to aid the reader in understanding the invention, and is not admitted to describe or constitute prior art to the invention.

Current methods for detecting the presence and/or determining the concentration of an analyte in a sample are generally complex and expensive. Sensitivity often comes at the cost of low selectivity and sometimes at the expense of slow operation.

Mass spectrometry is a commonly used analytical technique in which a sample is ionized and the ions are then separated according to their mass-to-charge ratio. Detection of the ions is by a device capable of detecting charged particles, such as an electron multiplier. The atoms or molecules in the sample can be identified through a fragmentation pattern. Mass spectrometry requires expansive and expensive instrumentation, and comprehensive training is required to operate the instruments and analyze the results. A devastating sample preparation process is also necessary for mass spectrometry, rendering this method unsuitable for the analysis of living cells.

Biosensors determine the concentration of an analyte by converting a biological response into an electrical signal. UV-vis spectrometry is commonly used for biosensing; exemplary applications include measurement of the concentration of glucose, lactic acid, and various ions. However, biosensing involving the use of UV-vis spectrometry is typically time-consuming and laborious. UV-vis spectrometry measures an analyte-specific absorption peak at a particular wavelength. As the concentration of the analyte is correlated with the value of the specific absorption peak, once a calibration curve of the analyte is obtained, the concentration of the analyte in the sample can be derived according to the calibration curve. However, impurities in a sample can affect the accuracy of the measurement of target analyte. Furthermore, calibration needs to be performed during each batch of sample testing.

Typical analytical methods often include electrochemical measurements, such as amperometric and potentiometric methods, which measure the current change that flows through the working electrode and counter electrode, or the potential change between the working electrode and reference electrode, respectively. In such methods, the current/potential change of the device serves as an indicator of the concentration of the target analyte in solution. Both amperometric and potentiometric methods currently suffer from low sensitivity and low selectivity.

Advances in the fabrication of organic semiconductive materials have allowed some improvements in the sensitivity of biosensors, in addition to a reduction in costs. Organic field-effect transistors (OFETs), which use organic semiconductor/s in their channels and an electric field to control the flow of current, are currently used for various biosensing applications. However, the transconductance of these devices is only sufficient for a limited range of biosensing applications.

Organic electrochemical transistors (OECTs) are a promising alternative to OFETs, and have been used in many different types of biosensors. A typical OECT consists of a gate electrode, an electrolyte, and source and drain electrodes connected by an organic semiconductor channel, which can be modulated through the electrolyte solution. The ions in solution are pushed in/out of the entire layer of the semiconductor channel after applying a gate potential to dope/de-dope the channel, thereby modulating the channel conductivity. An OECT can therefore serve as an ion-to-electron converter with high gain at a low operation voltage (less than 1 V), as large modulations in drain current can be achieved by the application of a relatively low gate voltage.

OECTs have been used for a variety of sensing applications due to their high gain, including the sensing of physical signals, chemicals, ions, cell barriers, proteins, DNA, and RNA. However, response times of OECTs can be slow. Biosensors based on OECTs also suffer from poor selectivity due to interference effects at the gate electrode; for example, the channel current of an OECT can be influenced by the ion concentration of the analyte solution, which is difficult to control in practical applications. When this occurs, the channel current response induced by the target analyte cannot be selectively obtained.

There is an unmet need for highly sensitive, selective, low-cost, fast and/or simple methods/devices which can be used to detect and and/or quantify specific analytes within a sample.

### SUMMARY

The present invention meets at least one of the needs mentioned above by providing devices and methods for fast, highly sensitive and/or highly selective detection of analyte/s within a sample. The invention provides a biosensor based on an organic electrochemical transistor (OECT) which uses the reaction of a target analyte with an oxidoreductase at a gate electrode to modulate the current at the drain electrode. The present inventors have found that interference at gate electrode/s can be effectively minimized by the introduction of a “reference” or “control” gate electrode which is not modified by an oxidoreductase. By applying a voltage to the control gate electrode, a stable channel current can be established. Switching the voltage to the gate electrode/s modified with an oxidoreductase provides a measurement which can be used as a selective indicator of the level of the analyte of interest.

In a first aspect, the present invention provides a transistor comprising:
a source electrode;
a drain electrode;
a channel comprising an organic semiconductor between the source electrode and the drain electrode;
a plurality of gate electrodes; and
an electrolyte,
   wherein the electrolyte contacts the gate electrodes and the channel, and wherein at least one of the gate electrodes comprises an oxidoreductase and at least one of the gate electrodes does not comprise an oxidoreductase.

In one embodiment of the first aspect, at least one of the gate electrodes comprises one or more of:
a copolymer of tetrafluoroethylene and perfluoro-3,6-dioxa-4-methyl-7-octene-sulfonic acid, and/or
polyalinine, and/or
chitosan or cellulose.

In one embodiment of the first aspect, the organic semiconductor comprises poly (3,4-ethylenedioxythiophene) polystyrene sulfonate (PEDOT:PSS).

In one embodiment of the first aspect, the organic semiconductor comprises poly (2-(3,3′-bis (2-(2-(2-methoxyethoxy) ethoxy) ethoxy)-[2,2′-bithiophen]-5-yl) thieno[3,2-b]thiophene), p(g2T-TT).

In one embodiment of the first aspect, the channel has a thickness of less than 200 nm, less than 190 nm, less than 180 nm, less than 170 nm, less than 160 nm, less than 150 nm, less than 140 nm, less than 130 nm, less than 120 nm, less than 110 nm, less than 100 nm, less than 90 nm, less than 80 nm, less than 70 nm, less than 60 nm, less than 50 nm, less than 40 nm, less than 30 nm, less than 20 nm, or less than 10 nm.

In one embodiment of the first aspect, the channel has a width to length ratio of 5, 4.5, 4, 3.5 or 3.

In one embodiment of the first aspect, the channel has a length of less than 100 μm, less than 90 μm, less than 80 μm, less than 70 μm, less than 60 μm, less than 50 μm, less than 40 μm, less than 30 μm, less than 20 μm, less than 10 μm, or less than 5 μm.

In one embodiment of the first aspect, at least one of the gate electrodes comprises platinum.

In one embodiment of the first aspect, the source electrode and/or the drain electrode comprises chromium and/or gold.

In one embodiment of the first aspect, the oxidoreductase forms part of a mixture comprising graphene and/or carbon nanotubes.

In one embodiment of the first aspect, the oxidoreductase is glucose oxidase, uricase, cholesterol oxidase or lactate oxidase.

In one embodiment of the first aspect, the plurality of electrodes comprises different oxidoreductases selected from two or more of:
glucose oxidase,
uricase,
cholesterol oxidase,
lactate oxidase.

In one embodiment of the first aspect, the transistor is a wearable sensor.

In one embodiment of the first aspect, the transistor further comprises a hydrophilic material and a collection receptacle.

In one embodiment of the first aspect, the collection receptacle comprises polydimethylsiloxane (PDMS).

In one embodiment of the first aspect, the transistor further comprises a meter for measuring electrical current.

In one embodiment of the first aspect, the meter is capable of connecting to a mobile phone application.

In one embodiment of the first aspect, the connecting is through short-wavelength UHF radio waves.

In a second aspect, the present invention provides a method for detecting an analyte in a test sample using the transistor according to the first aspect, the method comprising:
(i) applying a voltage to at least one of the gate electrodes which does not comprise an oxidoreductase;
(ii) applying the test sample to the transistor;
(iii) applying the voltage used in (i) to at least one of the gate electrodes which comprises an oxidoreductase,
(iv) removing the voltage from the gate electrode/s of part (i);
   wherein (iii) and (iv) occur simultaneously, and wherein a change in channel current after (iii) and (iv) indicates the presence of the analyte in the test sample.

In one embodiment of the second aspect, the detecting further comprises repeating (i) to (iv) using a control sample in place of the test sample in (ii) and comparing the change in channel current after (iii) and (iv) using the test sample with the change in channel current after (iii) and (iv) using the control sample.

In one embodiment of the second aspect, the voltage is less than 1 V, less than 0.9 V, less than 0.8 V, less than 0.7 V, less than 0.6 V, less than 0.5 V, less than 0.4 V, less than 0.3 V, less than 0.2 V, or less than 0.1 V.

In one embodiment of the second aspect, the test sample comprises
sweat,
saliva,
tears,
urine, or
blood.

In one embodiment of the second aspect,
the oxidoreductase is glucose oxidase and the analyte is glucose, or
the oxidoreductase is lactate oxidase and the analyte is lactic acid, or
the oxidoreductase is uricase and the analyte is uric acid, or
the oxidoreductase is cholesterol oxidase and the analyte is cholesterol.

In one embodiment of the second aspect, the plurality of electrodes of the transistor comprises different oxidoreductases selected from two or more of:
glucose oxidase,
uricase,
cholesterol oxidase,
lactate oxidase.

In one embodiment of the second aspect, the analyte comprises any one or more of:
glucose,
uric acid,
cholesterol,
lactic acid.

In a third aspect, the present invention provides a method for determining the concentration of an analyte in a test sample using the transistor according to the first aspect, the method comprising:
(i) applying a voltage to at least one of the gate electrodes which does not comprise an oxidoreductase;
(ii) applying the test sample to the transistor;
(iii) applying the voltage used in (i) to at least one of the gate electrodes which comprises an oxidoreductase;
(iv) removing the voltage from the gate electrode/s of (i);
   wherein (iii) and (iv) occur simultaneously, and wherein a change in channel current after (iii) and (iv) indicates the concentration of the analyte in the test sample.

In one embodiment of the third aspect, the determining further comprises repeating (i) to (iv) using a control sample in place of the test sample in (ii) and comparing the change in channel current after (iii) and (iv) using the test sample with the change in channel after (iii) and (iv) using the control sample.

In one embodiment of the third aspect, the voltage is less than 1 V, less than 0.9 V, less than 0.8 V, less than 0.7 V, less than 0.6 V, less than 0.5 V, less than 0.4 V, less than 0.3 V, less than 0.2 V, or less than 0.1 V.

In one embodiment of the third aspect, the test sample comprises
sweat,
saliva,
tears,
urine, or
blood.

In one embodiment of the third aspect, the plurality of electrodes of the transistor comprises different oxidoreductases selected from two or more of:
glucose oxidase,
uricase,
cholesterol oxidase,
lactate oxidase.

In one embodiment of the third aspect, the analyte comprises any one or more of:
glucose,
uric acid,
cholesterol,
lactic acid.

### Definitions

Certain terms are used herein which shall have the meanings set forth as follows.

As used in this application, the singular form “a”, “an” and “the” include plural references unless the context clearly dictates otherwise.

As used herein, the term “comprising” means “including”. Variations of the word “comprising”, such as “comprise” and “comprises” have correspondingly varied meanings.

As used herein, the term “plurality” means more than one. In certain specific aspects or embodiments, a plurality may mean 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, 50, 51, or more, and any numerical value derivable therein, and any range derivable therein.

As used herein, the term “between” when used in reference to a range of numerical values encompasses the numerical values at each endpoint of the range.

As used herein, the terms “source electrode” and “drain electrode”, when used in reference to a transistor, refer to the electrodes that transmit and receive an electrical current respectively across a semiconductive material.

As used herein, the term “gate electrode”, when used in reference to a transistor, refers to the electrode that controls the flow of electrical current between the source and drain electrodes.

As used herein, the term “doping” will be understood to mean the process of introducing one or more impurities to the pure form of a semiconductor in order to modulate its conductivity. Said impurities will be referred to herein as “dopants”. The term “de-doping” will be understood to mean the process of removing one or more impurities from the pure form of a semiconductor in order to modulate its conductivity.

As used herein, the term “oxidoreductase” refers to an enzyme that catalyses the transfer of electrons from one molecule (the oxidant) to another molecule (the reductant). Non-limiting examples of terms by which oxidoreductases are often known in the art include “electrochemically active enzymes” and “redox enzymes”. Non-limiting examples of oxidoreductases include oxidases, dehydrogenases, peroxidases, hydroxylases, oxygenases and reductases.

### BRIEF DESCRIPTION OF THE DRAWINGS

The above and other aspects and embodiments of the present disclosure will become apparent from the following description of the disclosure, when taken in conjunction with the accompanying drawings, in which:

FIG. 1 provides an exemplary illustration of a dual-gate OECT, showing the source and drain electrodes, two gate electrodes, the channel and an electrolyte. The two gate electrodes are shown as the Outer gate (Gate 1) and the Inner gate (Gate 2).

FIG. 2 provides an exemplary illustration of a gate modification strategy for a dual-gate OECT used as biosensor. Polyaniline, chitosan and glucose oxidase are abbreviated as PANI, CHIT and GOx respectively.

FIG. 3 provides transfer curves of a dual-gate OECT gated by the Pt inner gate, Pt outer gate and a Pt wire respectively. Channel dimensions: W=120 μm, L=30 μm and d=30 nm. V_{D}=0.05 V and V_{G}=0.3 V.

FIG. 4 is a graph which shows the current response of a dual-gate OECT after adding PBS solution and switching to the Pt outer gate. Channel dimensions: W=120 μm, L=30 μm and d=30 nm. V_{D}=0.05 V and V_{G}=0.3 V.

FIG. 5 is a graph which shows the effect of the channel thickness on the stabilization time of the channel current of an OECT after adding PBS solution (the first dropping point of the curve). The devices have a channel length (L) of 30 μm and a channel width (W) of 60 μm.

FIG. 6 is a graph which shows the effect of the channel length on the stabilization time of the channel current of an OECT after adding PBS solution (the first dropping point of the curve). The channel thickness is fixed at 30 nm. The V_{D} (drain voltage) and V_{G} (gate voltage) were fixed at 0.05V and 0.3V respectively.

FIG. 7 provides graphs (A-D) showing the channel current response curves of a dual-gate OECT for glucose detection ranging from 1 nM to 100 nM. The black arrows show the addition of glucose solution (gated through the control gate) and arrows show the gate voltage switching from the control gate to the enzymatic gate.

FIG. 8 provides graphs (A-C) showing the effective gate voltage changes of a dual-gate OECT in response to the addition of different concentrations of glucose.

FIG. 9 provides graphs showing the negligible channel current responses of a dual-gate OECT following the introduction of physiological levels of interfering compounds and switching the gate voltage to the enzymatic gate: (A) ethanol; (B) ascorbic acid; (C) urea; (D) uric acid; (E) lactic acid.

FIG. 10 provides (A) photographs and contact angles of four different kinds of commercial cloth; (B) provides an illustration of an exemplary design of a sweat capture structure which combines a sweat absorption layer integrated with a PDMS collection well in the dual-gate biosensor.

FIG. 11 is a photograph of an integrated dual-gate device worn on the wrist of a subject performing efficient sweat collection and quick and wireless detection of metabolites in human bodily fluids.

FIG. 12 is a schematic which shows how the integrated dual-gate biosensor can be worn on different parts of the human body.

FIG. 13 is a graph showing the on body channel current response of an integrated dual-gate biosensor worn on the fingertip to the secretion of sweat.

FIG. 14 is a graph showing the transfer curve of an integrated dual-gate biosensor worn on the fingertip following the secretion of sweat.

### DETAILED DESCRIPTION

The present invention provides devices for fast, highly sensitive and/or highly selective detection of analyte/s within a sample.

The devices of the present invention are biosensors based on organic electrochemical transistors (OECTs). The devices can afford a level of selectivity that is superior to equivalent biosensors based on OECTs due to factors including: (i) a dual or multi-gate electrode configuration; and/or (ii) target analyte-specific functionalization of one or more of the gate electrodes; and/or (iii) at least one gate electrode without target analyte-specific functionalization.

The present invention relates to these devices and methods for the use thereof in the detection and/or quantitation of analyte/s. The various features of the invention described below should not be considered limiting unless the context clearly indicates that to be the case.

### Design and Manufacture of the Transistors

The present invention provides biosensors based on OECTs and methods for their use. OECTs were first developed in the mid-1980s and are well known in the art. A typical OECT consists of one gate electrode, a source electrode, a drain electrode, an electrolyte, and an organic semiconductor channel. The gate electrode is immersed in the electrolyte, which is in contact with the organic semiconductor channel. The OECTs of the present invention include at least one additional gate electrode, which is also immersed in the electrolyte. The gate electrode voltage of an OECT controls the injection of ions from the electrolyte into the semiconductor channel and thereby the redox state of the channel and the current flowing between the source and drain electrodes. Those skilled in the art are well aware of the considerable flexibility in device architecture of OECTs, and no particular limitation is placed with regards to the arrangement of the components within the OECTs of the present invention.

A wide variety of materials may be used to manufacture the electrodes of the OECTs of the present invention. The material used for the gate electrode/s should be functionally matched with the material of the organic semiconductor channel, which may also be selected from a variety of alternatives. Non-limiting examples of suitable materials for the gate, source and/or drain electrodes include platinum, gold, titanium, chromium, silver, silver chloride, tungsten, stainless steel, iridium, calomel (mercury chloride), platinum-ruthenium alloy, palladium and carbon-based materials (for example, carbon nanotubes, graphene, reduced graphene oxide), or any combination thereof.

The gate, source and/or drain electrodes may be polarizable or non-polarizable. Non-limiting examples of materials which may be used to manufacture polarizable electrodes include platinum and/or gold. Non-limiting examples of non-polarizable electrodes include silver and/or silver chloride electrodes. In some embodiments of the invention one or more of the gate electrodes comprise platinum and/or one or more of the source and/or drain electrodes comprise chromium, silver or a combination of the two metals.

The channel of the OECTs of the invention comprises a semiconducting polymer, which is “doped/dedoped” via the injection of ions from the electrolyte by the application of a voltage to the gate electrode. “Doping” is the process of introducing one or more impurities to the pure form of a semiconductor in order to modulate its conductivity. This occurs in two main ways: electrons can be removed from the conjugated polymer backbone and the positive charges created are neutralized by counter anions (“p-type doping”), or electrons can be added to the conjugated polymer backbone from the dopant and the negative charges formed are balanced by counter cations (“n-type doping”). In the former process mobile holes are created which become the charge carriers (depletion mode) and mobile electrons carry the charge in the latter scenario (accumulation mode). The OECTs of the present invention may work in depletion mode or accumulation mode.

Without placing any particular limitation on the materials that may be used as semiconductors in the channels of the OECTs of the present invention, certain characteristics may be desirable. For example, the semiconducting polymers may have a capacity for high electronic conductivity, facile deposition, electrochemical stability in aqueous electrolytes and/or be commercially available in the form of aqueous dispersions. Crosslinkers may be added to the polymers to render them insoluble in water. Non-limiting examples of suitable crosslinkers include (3-glycidyloxypropyl) trimethoxysilane and/or divinylsulfone.

In some embodiments of the invention, the organic semiconducting channel comprises poly (3,4-ethylenedioxythiophene) doped with polystyrene sulfonate (PEDOT:PSS), which is p-type doped and works in depletion mode. In further embodiments, the channel comprises poly (2-(3,3′-bis (2 (2-(2-methoxyethoxy) ethoxy) ethoxy)-[2,2′-bithiophen]-5-yl) thieno[3,2-b]thiophene) p(g2T-TT), which works in accumulation mode and is n-type doped. Other non-limiting examples of suitable materials for the channel include poly (3-methylthiophene) (P3MT), polypyrrole (Ppy), polyaniline, polycarbazole, poly((ethoxy) ethyl 2-(2-(2-methoxyethoxy) ethoxy)acetate)-naphthalene-1,4,5,8-tetracarboxylic-diimide-co-3,3′-bis(2-(2-(2-methoxyethoxy) ethoxy) ethoxy)-(bithiophene)) (p(gNDI-g2T)), 2,6-dibromonaphthalene-1,4,5,8-tetracarboxylic diimide-co-monomers p(gNDI-gT2), poly (3-exylthiophene) (P3HT), alkoxy-benzo[1,2-b:4,5-b′]dithiophene (BDT) copolymers, poly(benzimidazobenzophenanthroline) (BBL) and/or poly (3-carboxyl-pentyl-thiophene) (P3CPT). Suitable semiconducting polymers may be synthesized by solution, vapour-phase and/or electrochemical polymerization, all of which are techniques very familiar to those skilled in the art.

Other conjugated polymer composites based on PEDOT may be suitable for channel material. For example, (trifluoromethylsulfonyl) sulfonylimide (TFSI) side groups can be attached to polystyrene or polymethacrylate and used with PEDOT in the channels-(PEDOT:PSTFSI) or PEDOT:PMATFSI respectively. Tosylate (p-toluenesulfonate) (PEDOT:Tos) is another suitable material. No particular limitation exists in relation to the electrolyte used in the OECTs. Non-limiting examples of suitable electrolytes include sodium chloride, potassium chloride, calcium chloride and magnesium chloride.

Additional polymers may be coated on one or more electrodes. In some embodiments, one or more additional polymers are added to one or more of the gate electrodes. A copolymer of tetrafluoroethylene and perfluoro-3,6-dioxa-4-methyl-7-octene-sulfonic acid may be added to one or more gate electrodes. This polymer is often referred to by those skilled in the art as Nafion. The coating of the copolymer of tetrafluoroethylene and perfluoro-3,6-dioxa-4-methyl-7-octene-sulfonic acid may block access of interfering molecules such as negative species to the gate electrode/s. Other non-limiting examples of polymers which may be added to electrodes include polyalinine, chitosan and/or cellulose. In some embodiments of the invention, graphene and/or reduced graphene oxide (rGO) flakes are immobilized on one or more electrodes. These electrodes may be the gate electrodes. The addition of functional polymers to the gate electrodes may increase the gate selectivity and/or enzyme loading capacity. In some embodiments, chitosan and/or cellulose may be used to anchor an enzyme to one or more gate electrode/s. Additionally or alternatively, the addition of one or more layers of polymers to the electrodes may block interfering compounds, contributing to higher selectivity for the target analyte/s.

In some embodiments of the invention, the configuration of the plurality of gate electrodes and/or the addition of one or more layers of polymers to the gate electrode/s contributes to higher selectivity of the devices for the target analyte/s by blocking the detection of interfering compounds. Non-limiting examples of such interfering compounds include uric acid, ascorbic acid, cholesterol, and dopamine, as well as ions (for example, sodium and/or potassium).

An oxidoreductase may be added to one or more gate electrodes. At least one gate electrode will not comprise an oxidoreductase. Non-limiting examples of oxidoreductases which may be coated on one or more gate electrodes include glucose oxidase, uricase, cholesterol oxidase, peroxidase and/or lactate oxidase. In some embodiments, the oxidoreductase may be mixed with nanomaterials such as, for example, graphene and/or carbon nanotubes. Mixing the enzyme/s with nanomaterials/s may have the effect of increasing the catalytic activity of the enzyme/s, which in turn could increase the sensitivity of the OECT. A crosslinker may be used to immobilize an oxidoreductase on one or more gate electrodes. Glutaraldehyde is one of many crosslinkers which could be used for this purpose. In some embodiments of the invention, one oxidoreductase is used in each device. In further embodiments, more than one oxidoreductase is used in a device, and different oxidoreductases are immobilized on different gate electrodes. In another non-limiting embodiment, an array of immobilized oxidoreductases is used within one device for the multiplex detection of metabolites in a sample. A person skilled in the art would be well aware of the many enzyme-substrate pairs which would be suitable for use with the present invention (see, by way of non-limiting example, Nguyen et al. Materials 12 (121) 2019:1-34).

Without limitation, one exemplary embodiment of the invention may have two gate electrodes, gate 1 and gate 2. Gate 1 may comprise layers of a copolymer of tetrafluoroethylene and perfluoro-3,6-dioxa-4-methyl-7-octene-sulfonic acid, polyalinine and/or chitosan, and will not comprise an oxidoreductase. Gate 2 may comprise layers of a copolymer of tetrafluoroethylene and perfluoro-3,6-dioxa-4-methyl-7-octene-sulfonic acid, polyalinine and/or chitosan, and an oxidoreductase. A further embodiment may comprise cellulose in place of or in addition to chitosan on one or both gate electrodes.

No particular limitation exists in relation to the dimensions of any of the components of the OECTs. In some embodiments, the channel has a thickness of less than 200 nm, less than 190 nm, less than 180 nm, less than 170 nm, less than 160 nm, less than 150 nm, less than 140 nm, less than 130 nm, less than 120 nm, less than 110 nm, less than 100 nm, less than 90 nm, less than 80 nm, less than 70 nm, less than 60 nm, less than 50 nm, less than 40 nm, less than 30 nm, less than 20 nm, or less than 10 nm. Additionally or alternatively, the channel may have a width to length ratio of 5, 4.5, 4, 3.5 or 3. Again, no limitation exists with regard to the relative dimensions of the channel.

The length of the channel may be less than 100 μm, less than 90 μm, less than 80 μm, less than 70 μm, less than 60 μm, less than 50 μm, less than 40 μm, less than 30 μm, less than 20 μm, less than 10 μm, or less than 5 μm.

No limitation applies in relation to the area of any of the electrodes. The size of the electrodes may be selected by the person skilled in the art to suit their application. Gate electrodes with a larger surface area may be capable of holding more oxidoreductase.

All of the dimensions of the OECTs of the present invention may be tuned by the person skilled in the art to modulate outcomes, for example, the channel current stabilization time. By way of non-limiting example, a comprehensive review of OECTs, methods for their fabrication and materials used in the manufacture thereof is included in Liao et al. Advanced Materials 27 (46) 2015:7493-7527.

### Operation of the Transistors

In exemplary methods using the devices of the invention, a voltage is applied to at least one gate electrode which does not comprise an oxidoreductase (control gate/s), in the presence of a sample containing target analyte/s (the test sample). Once the channel current has stabilized, the gate voltage is switched to at least one gate electrode comprising an oxidoreductase (enzymatic gate/s). The current change is recorded during the switching of the gate voltage from the control gate/s to the enzymatic gate/s and converted into the effective gate voltage change (V_{G}^{eff}). The V_{G}^{eff} can be regarded as an indicator of the presence and/or concentration of target analyte/s in the test sample. In further exemplary methods, the aforementioned process is repeated by contacting a sample in the transistor which does not contain the target analyte/s (the control sample). The V_{G}^{eff} obtained using the test sample is compared to the V_{G}^{eff} obtained using the control sample. In some embodiments, the V_{G}^{eff} obtained using the test sample minus the V_{G}^{eff} obtained using the control sample can be regarded as an indicator of the presence and/or concentration of target analyte/s in the test sample. In further embodiments, the gate voltage is removed from at least one control gate at the same time as it is applied to at least one enzymatic gate.

An equation explaining the reaction of the analyte during gate switching is:

$${I}_{DS} = \frac{2 π D}{L} {μ}_{p} {C}_{i} ( {V}_{p} - {V}_{G}^{eff} + \frac{{V}_{DS}}{2} ) {V}_{DS} ( when {IV}_{DS} ≪ \vert {V}_{p} - {V}_{G}^{eff} \vert )$$

$${V}_{p} = {qp}_{0} t / {C}_{i}$$

$${V}_{G}^{eff} = {V}_{G} + {V}_{offset}$$

After applying the gate voltage to the first gate, the channel current decreases due to the gating effect of the gate voltage:

$${I}_{DS} = \frac{2 π D}{L} {μ}_{p} {C}_{i} ( {V}_{p} - {V}_{G} + \frac{{V}_{DS}}{2} ) {V}_{DS} ( when {IV}_{DS} ≪ \vert {V}_{p} - {V}_{G} \vert )$$

$${V}_{p} = {qp}_{0} t / {C}_{i}$$

In some embodiments of the invention, the voltage applied to the control gate/s and/or the enzymatic gate/s is less than 1 V, less than 0.9 V, less than 0.8 V, less than 0.7 V, less than 0.6 V, less than 0.5 V, less than 0.4 V, less than 0.3 V, less than 0.2 V, or less than 0.1 V.

In further embodiments, the drain-source voltage is less than 0.1 V, less than 0.09 V, less than 0.08 V, less than 0.07 V, less than 0.06 V, less than 0.05 V, less than 0.04 V, less than 0.03 V, less than 0.02 V, or less than 0.01 V.

### Exemplary Applications of the Transistors

The transistors of the present invention may find particular application as wearable sensors. A skilled person in the art will readily recognise that the OECTs described herein could easily be incorporated into wearable products which could be used for the real time, personalized and/or non-invasive in situ monitoring of target analyte/s in samples such as bodily fluids.

In one exemplary and non-limiting embodiment, an OECT of the present invention may be incorporated into a wearable device. The device may further comprise a hydrophilic material and/or a collection receptacle. The hydrophilic material may be any suitable hydrophilic cloth or textile. A non-limiting example of a suitable material for the collection receptacle is polydimethylsiloxane (PDMS). The PDMS may comprise microfluidic channels. No particular limitation exists in relation to the part of the body on which the wearable sensor should be placed. Non-limiting examples of locations in which to place the wearable product include the forearm, fingertip, wrist, forehead, chest, and abdomen. In some wearable embodiments of the present invention, a hydrophilic cloth or textile may act as a filter at the skin-device interface to decrease contamination of the sample from the skin surface.

Further wearable embodiments of the present invention comprise a mobile meter. The meter may wirelessly detect and/or measure the concentration of analyte/s within a sample. In some exemplary embodiments, the meter is capable of connecting to a mobile phone application. The connecting may be via short-wavelength UHF radio waves. Some embodiments of the invention may use Bluetooth. In some non-limiting embodiments of the invention, the meter comprises a central microprocessor, analog to digital circuits (ADC), digital to analog circuits (DAC), and/or a Bluetooth module. The meter and/or mobile phone application may also be capable of analysing data obtained from the transistors.

The wearable devices of the invention may be worn by any animal of economic, social or research importance including bovine, equine, ovine, primate, avian and rodent species. Accordingly, the subject may be a mammal such as, for example, a human or a non-human mammal.

The devices of the present invention may be used to detect and measure a range of analytes in a range of sample types. Non-limiting examples of samples which may be tested using the transistors include sweat, saliva, tears, urine, and/or blood. Non-limiting examples of target analytes include glucose, lactate, uric acid, and/or cholesterol. In some non-limiting embodiments of the invention, the oxidoreductase is glucose oxidase and the analyte is glucose, and/or the oxidoreductase is lactate oxidase and the analyte is lactic acid, and/or the oxidoreductase is uricase and the analyte is uric acid, and/or the oxidoreductase is cholesterol oxidase and the analyte is cholesterol.

In one non-limiting example, the wearable devices of the present invention could be used in real time to monitor the levels of glucose, lactic acid and/or uric acid in sweat. The use of a hydrophilic cloth or textile and/or a collection receptacle could obviate the need for inducing sweat in order to obtain a sample of sufficient quantity for testing. Such monitoring has potential, for example, for predictive healthcare and for monitoring the physiology of athletes during exercise.

Many analytes that could be detected and/or measured using the devices of the present invention have important health implications. For example, the devices and methods could be used to monitor glucose levels in diabetic patients, to test for gout using levels of uric acid and/or to assess the risk of cardiovascular disease using cholesterol levels.

It will be appreciated by persons of ordinary skill in the art that numerous variations and/or modifications can be made to the present invention as disclosed in the specific embodiments without departing from the spirit or scope of the present invention as broadly described. The present embodiments are, therefore, to be considered in all respects as illustrative and not restrictive.

### Example—Fabrication and Testing of a Wearable Dual-Gate OECT-Based Biosensor

The present invention will now be described with reference to the following specific Example, which should not be construed as in any way limiting.

### Materials and Reagents

Poly(3,4-ethylenedioxythiophene)-polystyrene sulfonate (PEDOT:PSS) (Clevios PH 500) and phosphate-buffered saline (PBS) were stored at 4° C. AZ5214 and SU-8 2002 photoresists were stored away from direct light. The base elastomer and curing agent were mixed with a weight ratio of 10:1 and cured at 70° C. for 3 hours to form polydimethylsiloxane (PDMS) for further use.

### OECT Device Fabrication

The exemplary OECT microfabrication included the deposition of metal, PEDOT:PSS, and an insulation layer, through multi-layer photolithography. A polyethylene terephthalate (PET) film (0.2 mm) was annealed at 120° C. for 1 hour to promote polymer chain reorganization and decrease its deformation during further fabrication processes. The film was then thoroughly washed by sonication with acetone, deionized water, and isopropyl alcohol, respectively, followed by blow drying with high purity nitrogen. AZ5214 photoresist was spin coated on the PET film and exposed to ultraviolet radiation using a Karl Suss MA6 Mask aligner. The exposed film was developed in an AZ 300K developer to define the pattern of metal pads, interconnects, and source/drain contacts of the OECT. Then Cr (˜10 nm)/Au (˜100 nm) electrodes were deposited on the defined pattern of the PET film by RF magnet sputtering and a lift off process was performed using acetone. The dual Pt gate electrodes (˜90 nm) were patterned and deposited using a similar process. The channel area was then patterned through another photolithography process. The PEDOT:PSS aqueous solution supplemented with 5% dimethyl sulfoxide ((DMSO), 5% glycerin, and 0.25% dodecylbenzenesulphonic acid (DBSA), was spin coated on the patterned channel area and annealed at 110° C. for 20 minutes to form a thin and semiconducting PEDOT:PSS film. The PEDOT:PSS pattern was subsequently defined through a further lift off process. The device was packed with SU-8 2002 negative photoresist using a final photolithography process to open the channel and dual gate windows.

### Gate Modification Strategies

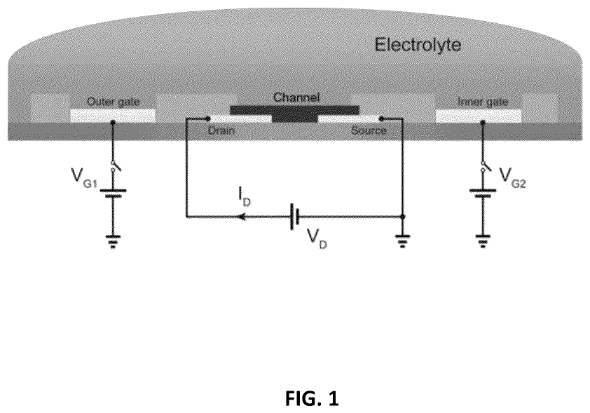

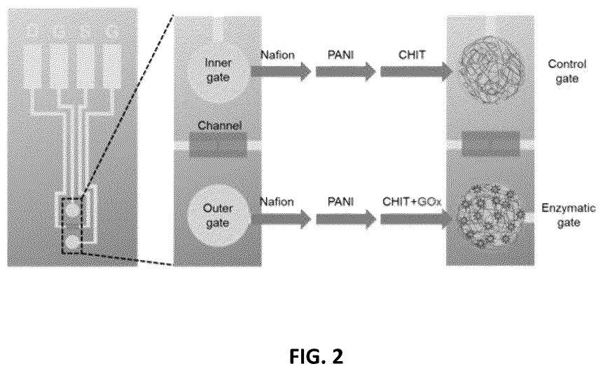

An exemplary illustration of a dual-gate OECT is provided in FIG. 1. The two gates of the exemplary device were modified with functional polymers and functional polymers/enzyme, respectively, in order to fabricate a highly sensitive biosensor. The two gates were first coated with a layer of a copolymer of tetrafluoroethylene and perfluoro-3,6-dioxa-4-methyl-7-octene-sulfonic acid (Nafion at 5 mg/mL) to block interference from most negatively-charged molecules. Polyaniline solution (10 mg/mL) was then drop coated on the Nafion-coated gates to increase the specific area of gate electrodes to increase the loading of the enzyme. One gate (the enzymatic gate) of the device was coated with glucose oxidase from aspergillis niger (10 mg/mL) in PBS solution and dried in a humidified environment at 4° C. Another gate (the control gate) of the same device was coated with PBS solution and also dried in humidified environment at 4° C. The coated enzyme on the enzymatic gate was then immobilized by drop-coating chitosan acetic solution (5 mg/mL; acetic acid: 50 mM). An exemplary illustration of this gate modification strategy is provided as FIG. 2. The resulting device was stored in a humidified environment at 4° C. Prior to sensing measurements, the device was rinsed with PBS solution to remove any unanchored enzyme.

### Sweat Absorption Layer Design and Device Assembly

The sweat absorption layer consisted of two-layer structure. A cloth with superhydrophobicity was finely tailored to fit the area of the channel and the two gates (about 0.5 cm²) and adhered to it by sealing the edge of the cloth. A thin PDMS well with a microfluidic channel on the top of the well was then bound with the cloth to form the sweat absorption layer (area: ˜1.5 cm²). Finally, the sweat absorption layer was integrated with the functional OECT device using the inherent adherence of PDMS. The as-prepared device was stored at 4° C. for future wearable applications.

### Device Characterization

A voltage (V_{D}) was applied between the drain and source electrodes on which the PEDOT:PSS film was spin coated and the current (I_{D}) flowing through the channel was monitored. Two identical voltages (V_{G1} and V_{G2}) were applied on the two platinum gates, respectively. Two switches connected to the two gates were switched off during the initial state. Then the inner gate switch was turned on and electrolyte was subsequently dripped on the sensing area of the device. The cations in the electrolyte were injected into the whole volume of the channel which compensated the counter ions (PSS⁻) in the PEDOT:PSS film and de-doped it, thereby decreasing the conductivity of the channel.

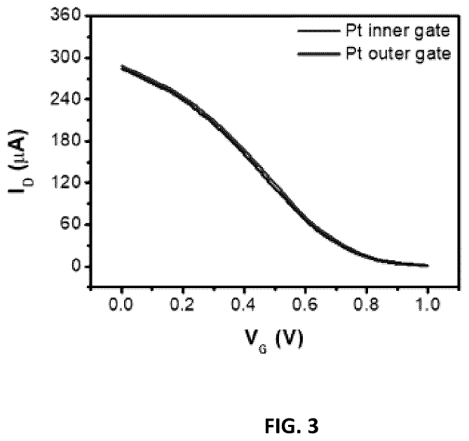

Measurements of the transfer curves and real time channel current responses at a certain gate voltage were performed by two source meters (Keithley 2400) controlled through a Labview program in a laptop. For the measurement of the transfer curve of a device, the drain-source voltage (V_{DS}) was fixed at 0.05 V and the channel current was measured with the sweeping of gate voltage (V_{G}). As shown in FIG. 3, the transfer curves of a dual-gate device gated by its inner gate and its outer gate nearly overlapped. This indicates that the uniformity of the two gates of the device has been successfully realized. Gate uniformity guarantees the introduction of less interference and consequently, high accuracy using the dual-gate biosensing method.

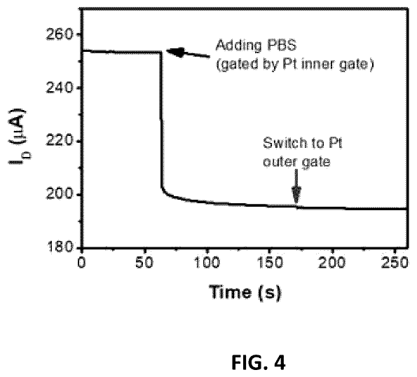

In further biosensing testing, the outer gate voltage was turned on and the inner gate voltage was turned off after the channel current stabilized. The change in channel current after gate voltage switching can be regarded as an indicator of a specific analyte level when the two gates are further modified with the functional polymers and corresponding enzyme as described above. The current change of the channel was negligible after switching gate voltage from the inner gate to the outer gate, further confirming the good gate uniformity (FIG. 4).

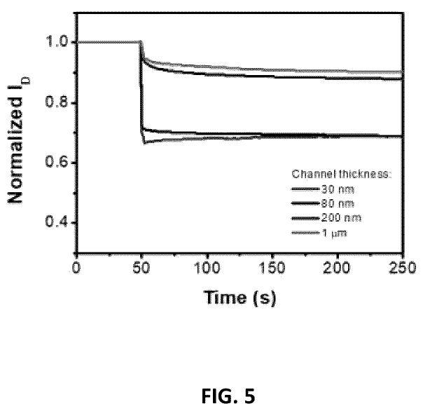

To study the effect of channel dimensions on the stabilization of the channel current of devices after applying a gate voltage of 0.3 V, four channel thicknesses were chosen: 30 nm, 80 nm, 200 nm, and 1 μm. The PEDOT:PSS film thickness was adjusted by changing the spin speed during the PEDOT spin coating process. The channel length for all four devices was 30 μm and a Pt gate was used during the characterization of the channel current response times of the devices according to their dimensions. Profile curves of PEDOT films using different fabrication conditions were used to confirm film thicknesses. Accordingly, the film thickness was estimated at different film spinning speeds (6000 rpm, 1500 rpm*2, 500 rpm*2, and drop cast). The two response behaviors of the channel currents for the devices with the four different channel thicknesses is provided in FIG. 5.

FIG. 5 shows the gradual current decay for the devices with thicker channels and the spike-and-recovery channel currents for the devices with thinner channels devices after application of a gate voltage of 0.3 V. The transient behavior of the channel current can be determined by:

$$I ( t , {V}_{G} ) = {I}_{D} ( {V}_{G} ) + Δ {I}_{D} ( 1 - f \frac{{τ}_{e}}{{τ}_{i}} ) exp ( - \frac{t}{{τ}_{i}} ) \qquad ( 1 )$$

I_{D} is the channel current at steady state and fixed gate voltage (V_{G}) and ΔI_{D}=I_{D} (V_{G}=0)−I_{D} (V_{G}). f is a geometric factor (it can be considered as ½ when V_{G}>>V_{D}). τₑ and τᵢ are electronic and ionic transit time, respectively, where τₑ=L²/μV_{D} (L is the channel length, and μ is the mobility of the PEDOT:PSS film) and τᵢ=C_{d}·Rₛ (Cd is the device capacitance and Rs is the resistance of electrolyte). According to Equation 1, the transient response of the channel current to the applied voltage (V_{G}=0.3 V) can be a spike-and-recovery curve (fτₑ>τᵢ) or be a monotonic decay curve (fτₑ<τᵢ). The electronic transit time can be considered as a constant in this circumstance. The ionic transit time is proportional to the capacitance of the device. According to the capacitance equation: C=ε₀·A/d, the capacitance of channel increases with the increase in the film thickness since the area of the film increases substantially due to the thickness increase and the porous structure. The geometric factor (f) is approximately ½ due to V_{G}>>V_{D} (V_{G}=0.3 V, V_{D}=0.05 V, respectively). The transient response of the channel current shows monotonic decay behavior when the device has a thinner channel (30 nm). With the increase in channel thickness, the transient response of the channel current transforms from monotonic decay to spike-and-recovery behavior. As shown in FIG. 5, the current responses of the devices with channel thicknesses of 200 nm and 1 μm show much longer waiting times to reach a relatively stable state than those for the devices with channel thicknesses of 80 nm and 30 nm. The device with the thinnest channel was able to quickly reach a stable status following the application of a certain gate voltage because the thinner channel allowed the device to quickly perform ion exchange during the volumetric doping and de-doping process.

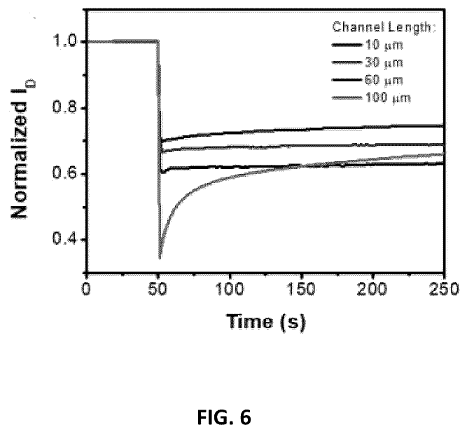

To check the effect of channel length on the response speed of the device channel current, OECT devices with different channel lengths (10 μm, 30 μm, 60 μm, and 100 μm) were fabricated and checked under a Leica microscope (DM1750M). The ratio of the width to the length of the channel was fixed at 4 for all devices. The channel thickness for all devices was 30 nm as this thickness can realize a quick channel current response. PBS solution was added to the channel area and the channel currents for channels with different dimensions were compared. As shown in FIG. 6, the spike-and-recovery response of the channel current was observed in device with all four channel lengths. According to the equation: τₑ=L²/μV_{D}, the τₑ increases with the increase of the channel length (L), thus enabling much bigger spikes and longer channel current response times for the device. It is consistent with Equation 1 that a larger τₑ can induce a larger spike-and-recovery response and therefore a longer stabilization time of the channel current after applying the gate voltage. It was found that the stabilization time of the channel current of devices with a channel length of 10 μm and 30 μm was quite similar. So, an OECT device with a 30 μm channel length is enough for quick stabilization of the channel current and is suitable for quick detection.

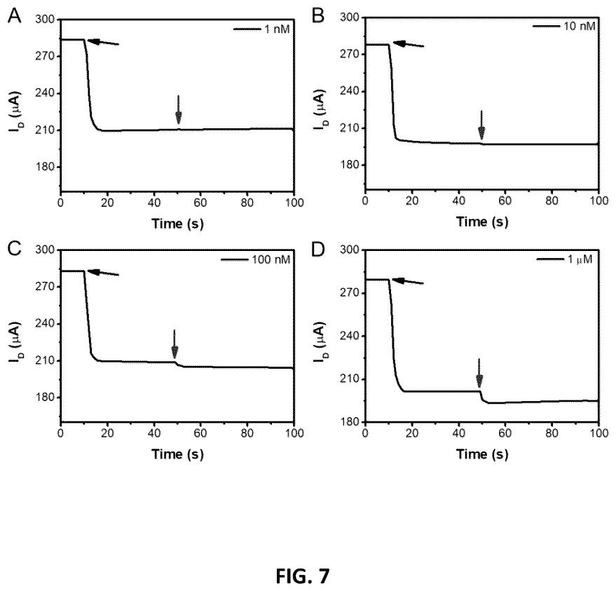

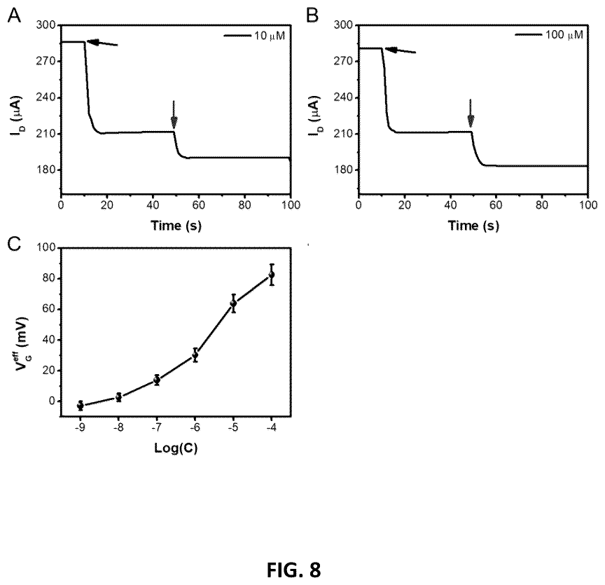

After modification to the gates as described above, the dual-gate glucose devices were used to perform a calibration test, in which different concentrations of glucose in PBS solution were added to the channel and gate areas of the device and the channel current change (ΔI_{D}) was recorded and converted to the effective change in gate voltage (ΔV_{g}^{eff}) during gate voltage (0.3 V) switching from the control gate to the enzymatic gate. The channel current of a dual-gate OECT device was first measured under control gate voltage during the addition of PBS with a certain concentration of glucose solution, then the gate voltage was switched to the enzymatic gate after the stabilization of the channel current. The current change was recorded during the switching of gate voltage from the control gate to the enzymatic gate and converted into the effective gate voltage change (V_{G}^{eff}). The V_{G}^{eff} can be regarded as the indicator of the concentration of glucose solution. Using this method, different concentrations of glucose solution were measured as a function of V_{G}^{eff} (FIGS. 7 and 8).

The current responses of the channels showed spike-and-recovery behavior in all the calibration curves as expected. This is consistent with the previous current responses shown in FIG. 6 in that thin channel OECTs behave like a capacitive current. The channel current quickly reached stabilization (in less than 40 s) after adding PBS solution (black arrow in FIG. 7A). The control test (no addition of glucose to the PBS solution) showed that there was no current response after switching to the enzymatic gate (arrow in FIG. 7A). The dual-gate OECT began to show an obvious response after the addition of 100 nM glucose solution with a detection sensitivity of 20.69 mV/decade (FIG. 7D). The channel current quickly dropped and reached stabilization after switching gate voltage to the enzymatic gate (arrow in FIG. 7D).

The dual-gate device with Pt gate electrodes was sensitive to H₂O₂ according to the anode reaction occurring on the gate:

$${H}_{2} {O}_{2} {⟶}^{Pt} 2 {H}^{+} + {O}_{2} + 2 e \qquad ( 2 )$$

The glucose oxidase on the gate electrode catalyzed the conversion of glucose into gluconolactone and was reduced in the process. A further redox reaction reactivated the reduced enzyme and produced hydrogen peroxide. The aforementioned redox reactions were cycled and produced more hydrogen peroxide when enough glucose was present in the solution. The hydrogen peroxide produced was catalyzed by the Pt gate electrode and oxidized into oxygen (as shown in equation 2), thus inducing electron transfer into the gate electrode and subsequently affecting the channel current. Glucose was sensed according to the above reaction mechanism and its concentration was proportional to the production of hydrogen peroxide during the enzymatic redox reaction and corresponding channel current change.

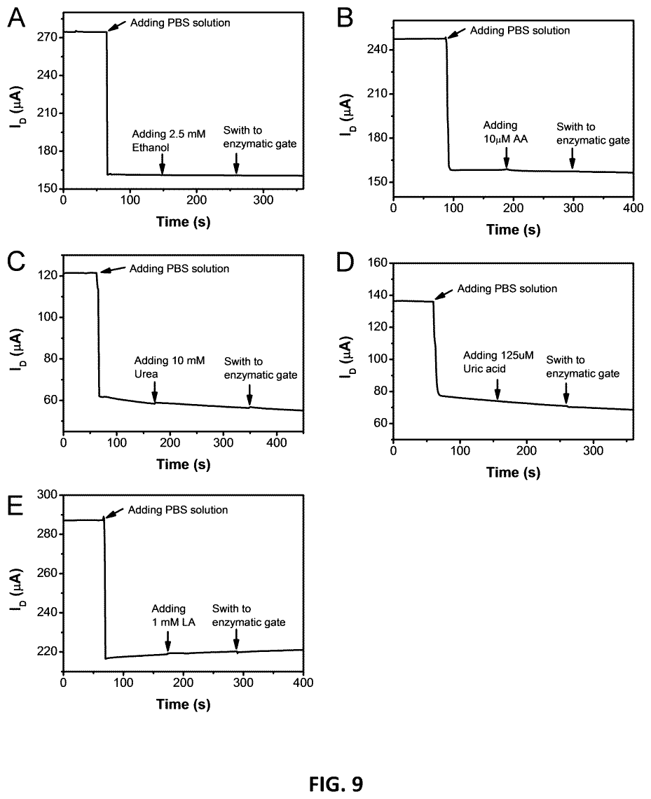

Interferences (ethanol, ascorbic acid, urea, uric acid, and lactic acid) were introduced in PBS solution to check the selectivity of the dual-gate glucose sensor. A negligible channel current response was observed after adding physiological levels of interferences and switching the gate voltage to the enzymatic gate (FIG. 9). This confirms that the selectivity of the device has been successfully realized by multilayer modification strategies.

Due to the dual-gate design, the device of the present invention can realize quick stabilization of channel current and effect a quick response to the addition of a target analyte solution. The device solves the problem of the long waiting times of the traditional single gate OECT detection technique before it reaches stabilization (usually taking about several hundred seconds).

The quick stabilization and response of the device make it suitable for use in wearable applications, such as for the quick detection and real time monitoring of physiological and biochemical parameters. The current response increased with the increase in glucose concentration and reached saturation when the glucose concentration was more than 100 μM (FIGS. 7 and 8). Thus, the detection limit of the dual-gate glucose sensor in this Example was down to 100 nM with a sensitivity of 20.69 mV/decade.

### Mobile Meter Design and Wearable Measurements

The dual-gate device can be worn on the wrist or fingertip as a wearable product and used for the biochemical detection of sweat. However, the sweating rate is relatively slow if no external stimulus is applied on a human subject. The sweating rate of an average healthy human ranges from 1 to 100 nL/min per gland according to their physical status with a density of ˜200 glands/cm². The area of the channel and the adjacent two gates of a device is about 10 mm² and it can only collect 20˜2000 nL sweat per minute when the device is adhered to the surface of human skin. The collected sweat is therefore insufficient to fully cover the gate and channel area of the device within dozens of minutes of collection time if the human is stationary for more than half an hour.

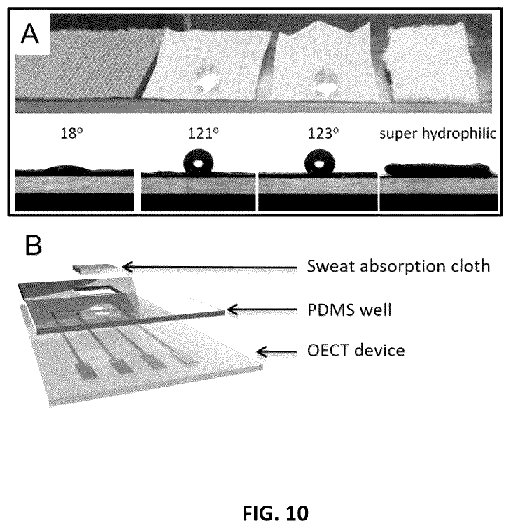

In order to realize in situ efficient sweat collection for biosensing applications, a sweat absorbent layer was developed to decrease the waiting time. As shown in FIG. 10A, the white thin cloth was superhydrophilic, and three other kinds of commercial cloth demonstrated weak ability to absorb sweat according to their contact angle against artificial sweat. The channel area and adjacent gates of the device were covered by the superhydrophilic cloth. The remaining parts of the device except the metal pads were covered by one thin PDMS well with a microfluidic channel against the skin surface. (FIG. 10B).

The device with the sweat absorption layer quickly collected enough sweat on the cloth to perform biosensing in less than 10 minutes. The superhydrophilic cloth was able to quickly absorb secreted sweat from nearby glands and form a sweat connection between the channel and gates underneath. Furthermore, the hydrophilic PDMS layer could repel the secreted sweat to its well through the microfluidic channel, which accelerated the sweat collection into the superhydrophilic cloth.

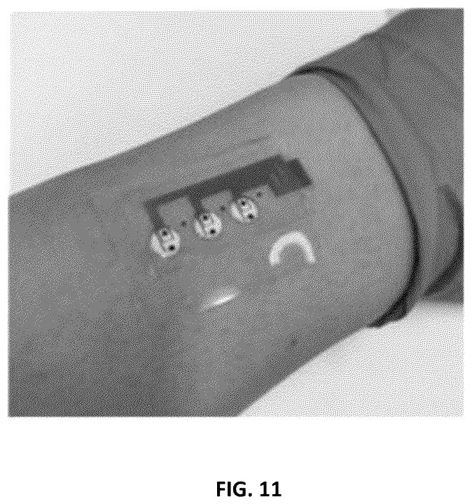

As shown in FIG. 11, the integrated device conformed well to skin and allowed quick and selective detection of a panel of metabolites in human perspiration. The flexible substrate integrated with the PDMS layer guaranteed a stable skin-sensor contact. The integrated superhydrophilic cloth avoided the direct contact of human skin with the channel and modified gates and decreased the disturbance introduced by friction between sensor and skin.

The portable meter consisted of four main modules: a central microprocessor, analog to digital circuits (ADC), digital to analog circuits (DAC) and a bluetooth module. The portable meter integrated with a microprocessor, control circuit, readout circuit, power management module, and wireless transmission module was connected to the sensor through a flexible cable and powered by a rechargeable lithium-ion battery (battery capacity: 340 mAh) at low power consumption. The meter could be remotely controlled by a mobile phone and enabled sensing data collected from the sensor to be transmitted to the custom app with a visualized interface and data logging functionalities. The portable meter could perform both transfer curve characterization and channel current response characterization and the tested results were barely discriminated from those obtained from Keithley 2400 source meters. The accuracy and reliability of the portable meter guarantee its further wearable integration with dual-gate OECTs.

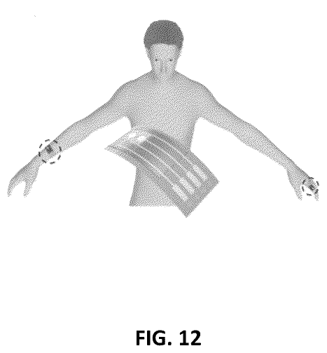

As shown in FIG. 12, the exemplary integrated wearable device connected to the portable meter may be worn on various parts of the body, such as the forearm, fingertip, forehead, chest, and abdomen. The portable meter connected to the sensor can easily be put in an armband or pocket.

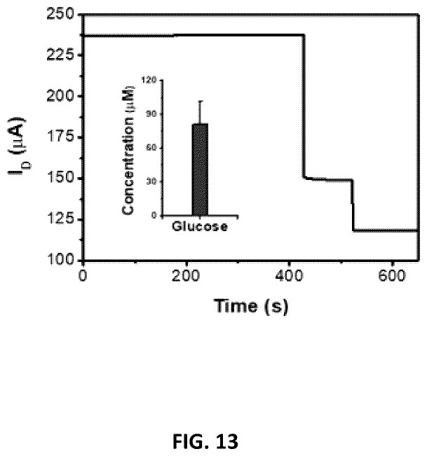

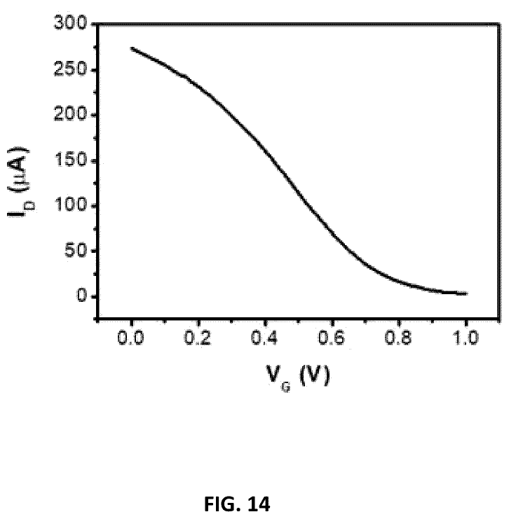

The real time channel current response of the device worn on a volunteer's fingertip under a medium exercise level was monitored by the mobile meter and visualized on a custom app on a mobile phone via Bluetooth for the detection of glucose in sweat (FIG. 13). The gate voltage was not applied to the channel of the sensor in the first seven minutes as there was not enough sweat in the PDMS well to connect its channel and gates. At the time point of about 420 s, the channel current decreased sharply because the superhydrophilic cloth in the PDMS well had collected enough sweat and established its solution connection. Due to the novel device design, the channel current quickly reached stabilization in a short period of time after the sharp decrease. The channel current underwent another minor decrease after switching the gate voltage to the enzymatic gate which can be regarded as the indicator of sweat glucose. The glucose concentration of the volunteer was about 77 μM according to the ΔV_{g}^{eff} (FIG. 14) and the calibration curve, which was in the expected range for a healthy person. The deviation of averaged glucose concentration was a little larger than expected during three repeated tests, which may have been due to the variance of the sweating rate. The wearable device can be used for sensing different metabolites, such as glucose, lactate acid, and uric acid in different human body fluids.

### INDUSTRIAL APPLICABILITY

The objective of the presently claimed invention is to provide devices that achieve highly sensitive, simple, fast, low cost and/or selective detection of biomarkers.

What is claimed:

1. A method for detecting an analyte in a test sample, the method comprising:
(i) providing a transistor comprising:
a source electrode,
a drain electrode,
a channel,
a plurality of gate electrodes, and
an electrolyte,
wherein the channel comprises an organic semiconductor between the source electrode and the drain electrode, the electrolyte contacts the plurality of gate electrodes and the channel, and at least one of the plurality of gate electrodes comprises an oxidoreductase and at least one of the plurality of gate electrodes does not comprise an oxidoreductase;
(ii) applying a voltage to at least one of the plurality of gate electrodes which does not comprise the oxidoreductase;
(iii) applying the test sample to the transistor;
(iv) applying the voltage used in (ii) to at least one of the plurality of gate electrodes which comprises the oxidoreductase; and
(v) removing the voltage from the at least one of the plurality of gate electrodes of (ii),
wherein (iv) and (v) occur simultaneously, and a change in channel current after (iv) and (v) indicates the presence of the analyte in the test sample.

2. The method according to claim 1, wherein the detecting further comprises repeating (ii) to (v) using a control sample in place of the test sample in (iii) and comparing the change in channel current after (iv) and (v) using the test sample with the change in channel current after (iv) and (v) using the control sample.

3. The method according to claim 1, wherein the voltage is less than 1 V, less than 0.9 V, less than 0.8 V, less than 0.7 V, less than 0.6 V, less than 0.5 V, less than 0.4 V, less than 0.3 V, less than 0.2 V, or less than 0.1 V.

4. The method according to claim 1, wherein the test sample comprises: sweat, saliva, tears, urine, or blood.

5. The method according to claim 1, wherein the oxidoreductase is glucose oxidase and the analyte is glucose, the oxidoreductase is lactate oxidase and the analyte is lactic acid, the oxidoreductase is uricase and the analyte is uric acid, or the oxidoreductase is cholesterol oxidase and the analyte is cholesterol.

6. The method according to claim 5, wherein the plurality of electrodes of the transistor comprises different oxidoreductases selected from two or more of: glucose oxidase, uricase, cholesterol oxidase, and lactate oxidase.

7. A method for determining the concentration of an analyte in a test sample, the method comprising:
(i) providing a transistor comprising:
a source electrode,
a drain electrode,
a channel,
a plurality of gate electrodes, and
an electrolyte,
wherein the channel comprises an organic semiconductor between the source electrode and the drain electrode, wherein the electrolyte contacts the plurality of gate electrodes and the channel, and at least one of the plurality of gate electrodes comprises an oxidoreductase and at least one of the plurality of gate electrodes does not comprise an oxidoreductase;
(ii) applying a voltage to at least one of the plurality of gate electrodes which does not comprise the oxidoreductase;
(iii) applying the test sample to the transistor;
(iv) applying the voltage used in (ii) to the at least one of the plurality of gate electrodes which comprises the oxidoreductase; and
(v) removing the voltage from the at least one of the plurality of gate electrode/s of (ii),
wherein (iv) and (v) occur simultaneously, and a change in channel current after (iv) and (v) indicates the concentration of the analyte in the test sample.

8. The method according to claim 7, wherein the determining further comprises repeating (ii) to (v) using a control sample in place of the test sample in (iii) and comparing the change in channel current after (iv) and (v) using the test sample with the change in channel after (iv) and (v) using the control sample.

9. The method according to claim 7, wherein the voltage is less than 1 V, less than 0.9 V, less than 0.8 V, less than 0.7 V, less than 0.6 V, less than 0.5 V, less than 0.4 V, less than 0.3 V, less than 0.2 V, or less than 0.1 V.

10. The method according to claim 7, wherein the test sample comprises sweat, saliva, tears, urine, or blood.

11. The method according to claim 7, wherein the plurality of electrodes of the transistor comprises different oxidoreductases selected from two or more of: glucose oxidase, uricase, cholesterol oxidase, and lactate oxidase.
